(19) United States
(12) Patent Application Publication
(10) Pub. No.: US 2022/0293786 A1
(43) Pub. Date: Sep. 15, 2022

(54) AN IMPROVED SHIELDED GATE TRENCH MOSFET WITH LOW ON-RESISTANCE

(71) Applicant: Fu-Yuan HSIEH, New Taipei City (TW)

(72) Inventor: Fu-Yuan HSIEH, New Taipei City (TW)

(73) Assignee: Nami MOS CO., LTD., New Taipei City (TW)

(21) Appl. No.: 17/197,081

(22) Filed: Mar. 10, 2021

(51) Int. Cl. H01L 29/78; H01L 29/66; H01L 29/26; H01L 27/088; H01L 21/8234; H01L 29/40; H01L 21/762

(52) U.S. Cl. CPC H01L 29/7813; H01L 29/66734; H01L 29/26; H01L 27/088; H01L 21/823462; H01L 29/401; H01L 21/76205

(57) ABSTRACT

An improved SGT MOSFET having low on-resistance is disclosed in this invention by adding a current spreading region under body region and a method to manufacture the same. With a doping concentration higher than the drift region, the inventive current spreading region can help reducing on-resistance while remaining a target breakdown voltage. Meanwhile, the present invention also features a method of formation of a new MSO structure with LOCOS technique for further improving on-resistance.

### FIELD OF THE INVENTION

This invention relates generally to semiconductor devices, and more particularly, to a shielded gate trench MOSFET (Metal Oxide Semiconductor Field Effect Transistor) with improved lower on-resistance and a method for manufacturing the same.

### BACKGROUND OF THE INVENTION

Please refer to FIG. 1A for a conventional shielded gate trench MOSFET (SGT) structure, compared with traditional single gate trench MOSFETs, the shielded gate trench MOSFET in FIG. 1A is more attractive due to lower gate charge and lower on-resistance as results of existence of oxide charge balance region in drift region and thick oxide underneath gate electrode.

FIG. 1B shows the doping concentration of majority carriers along A-B cross section of FIG. 1A, in which there is a parasitic N− region 101 formed as result of P body 102 diffusion into N epitaxial layer 103. When current flows from drain region through drift region and then N− region 101 to channel region, the lower doping concentration of N− region 101 will lead to a higher on-resistance, which will limit the performance of applications.

To further reduce the on-resistance, as shown in FIG. 1C, a SGT structure with multiple stepped oxide (MSO) in a single trench is disclosed in U.S. Pat. No. 9,716,009 with a specific on-resistance about 25% lower than the SGT MOSFET in FIG. 1A. However, formation of the MOS structure requires complicated manufacturing process, including multiple polysilicon deposition, multiple polysilicon etching and multiple oxide etching, which will rise uncertainty and cause cost inefficiency.

Moreover, for next generation of Synchronous rectifying applications, it requires further improving on-resistance for high frequency and high efficiency applications. Therefore, there is still a need in the art of the semiconductor device design and fabrication, particularly for SGT MOSFET design and fabrication, to provide a novel cell structure, device configuration and manufacturing process making a SGT MOSFET having lower on-resistance, uncomplicated manufacturing process for higher efficiency applications.

### SUMMARY OF THE INVENTION

The present invention discloses a SGT MOSFET with improved on-resistance by adding a current spreading region under body region and a method to manufacture the same. With a doping concentration higher than the drift region, the inventive current spreading region can help reducing the on-resistance while remaining a target breakdown voltage. Meanwhile, the present invention also features a method of formation of MSO with LOCOS (Local Oxidation of Silicon) technique, which is much cost effective than the prior art discussed above.

According to one aspect, the invention features a SGT MOSFET formed in an epitaxial layer of a first conductivity type onto a substrate of the first conductivity type, further comprising: a plurality of gate trenches surrounded by source regions of the first conductivity type are encompassed in body regions of a second conductivity type near a top surface of the epitaxial layer, each of the gate trenches is filled with a gate electrode and a shielded gate electrode, wherein the shielded gate electrode is insulated from the epitaxial layer by a first insulating film, the gate electrode is disposed above the shielded gate electrode and insulated from the epitaxial layer by a gate oxide, the shielded gate electrode and the gate electrode are insulated from each other by an IPO (inter-polysilicon oxide) film, the gate oxide surrounds the gate electrode and has less thickness than the first insulating film; an oxide charge balance region is formed between adjacent of the gate trenches; a current spreading region of the first conductivity type is formed below each of the body regions between adjacent of the gate trenches, the current spreading region has higher doping concentration than the epitaxial layer, and the body regions, the shielded gate electrodes, and the source regions is shorted to a source metal through a plurality of trench contacts.

According to another aspect, in some preferred embodiments, the first insulating film is a single oxide film having uniform thickness and the epitaxial layer is a single epitaxial layer having uniform doping concentration. In some other preferred embodiments, the first insulating film is a single oxide film having uniform thickness and the epitaxial layer comprises at least three sub-epitaxial layers of different doping concentration including a bottom epitaxial layer with resistivity R1, a middle epitaxial layer with resistivity R2 and a top epitaxial layer with resistivity R3, wherein R2<R3<R1 or R2<R1<R3. In some other preferred embodiments, the first insulating film has multiple stepped oxide (MSO) structure having greatest thickness padding lower portion and bottoms of the shielded gate electrode, and the epitaxial layer is a single epitaxial layer having uniform doping concentration. In some other preferred embodiments, the first insulating film has multiple stepped oxide structure having greatest thickness along lower portion sidewalls and bottoms of the gate trenches, and the epitaxial layer comprises at least three sub-epitaxial layers of different doping concentration including a bottom epitaxial layer with resistivity R1, a middle epitaxial layer with resistivity R2 and a top epitaxial layer with resistivity R3, wherein R3<R2<R1. In some other preferred embodiments, the first insulating film has two stepped oxide structure having a lower portion oxide along lower portion sidewalls and bottom of the gate trenches with greater thickness than an upper portion oxide, and the epitaxial layer comprises at least three sub-epitaxial layers of different doping concentration including a bottom epitaxial layer with resistivity R1, a middle epitaxial layer with resistivity R2 and a top epitaxial layer with resistivity R3, wherein bottom surface of the gate trenches is disposed in the bottom epitaxial layer, the middle epitaxial layer is adjacent to the lower portion oxide, the top epitaxial layer is adjacent to the upper portion oxide.

According to another aspect, the invention features a SGT MOSFET formed in an epitaxial layer of a first conductivity type onto a substrate of the first conductivity type, further comprising: a plurality of gate trenches surrounded by source regions of the first conductivity type are encompassed in body regions of a second conductivity type near a top surface of the epitaxial layer, each of the gate trenches is filled with a gate electrode and a shielded gate electrode, wherein the gate electrode is disposed above the shielded gate electrode and insulated from the epitaxial layer by a gate oxide; an oxide charge balance region is formed between adjacent of the gate trenches; a current spreading region is formed below each of the body regions between adjacent of the gate trenches; the body regions, the shielded gate electrodes and the source regions are shorted to a source metal through a plurality of trench contacts; each of the gate trenches further comprises a first type gate trench and a second type gate trench in the epitaxial layer, wherein: the first type gate trench is filled with the gate electrode and upper portion of the shielded gate electrode which is surrounded by a first insulating film; the second type gate trench is disposed below the first type gate trench and filled with lower portion of the shielded gate electrode which is surrounded by a second insulating film along sidewalls and bottom of the second type gate trench; the second insulating film has thickness greater than the first insulting film; the shielded gate electrode and the gate electrode are insulated from each other by an IPO film; and the gate oxide surrounds the gate electrode and has less thickness than first insulating film, the second insulating film, and the IPO film respectively.

According to another aspect, in some preferred embodiments, the second type gate trench has trench width less than the first type gate trench. In some other preferred embodiments, the second type gate trench has trench width same as the first type gate trench. In some other preferred embodiments, the second type gate trench has trench width greater than the first type gate trench.

According to another aspect, in some preferred embodiments, the first insulating film is combination of a thermal oxide and a deposited oxide. In some other preferred embodiments, the first insulating film is a thermal oxide.

According to another aspect, in some preferred embodiments, the epitaxial layer is a single epitaxial layer with uniform doping concentration. In some other preferred embodiments, the epitaxial layer comprises at least three sub-epitaxial layers of different doping concentration including a bottom epitaxial layer with resistivity R1, a middle epitaxial layer with resistivity R2 and a top epitaxial layer with resistivity R3, wherein R3<R2<R1. More preferred, the gate trenches each has a bottom surface disposed in the bottom epitaxial layer, the top epitaxial layer is adjacent to the first insulating film and the middle epitaxial layer is adjacent to the second insulating film.

The invention also features a method for manufacturing a SGT MOSFET having current spreading regions, comprising: (a) growing an epitaxial layer of a first conductivity type onto a substrate heavily doped with the first conductivity type. (b) forming a current spreading region on top of the epitaxial layer; (c) applying a hard mask composed of oxide/first nitride/oxide layers onto top surface of the epitaxial layer and etching a plurality of first type gate trenches by definition of the hard mask; (d) growing a thermal oxide layer lining inner surface of the first type gate trenches; (e) forming deposited oxide layer covering the thermal oxide layer and outer surface of said hard mask; (f) depositing a second nitride layer covering the deposited oxide layer; (g) performing anisotropic etch of nitride layer to remove the second nitride layer from bottom of the first type gate trenches; (h) performing anisotropic etch of oxide layer to remove the thermal oxide layer and the deposited oxide layer from bottom of the first type gate trenches; (i) performing anisotropic trench etch to form a plurality of second type gate trenches below the first type gate trenches; (j) growing another oxide layer lining inner surface of the second type gate trenches to serve as a second insulating film; (k) removing the second nitride layer; (l) depositing a first doped polysilicon layer and etching back to form shielded gate electrodes; (m) depositing a layer of IDP oxide; (n) performing oxide CMP till touching the first Nitride layer in the hard mask and removing the first nitride layer; (o) performing wet oxide etch to a target depth below top surface of the current spreading regions.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

The accompanying drawings, which are included to provide a further understanding of the invention and are incorporated in and constitute a part of this specification, illustrate exemplary embodiments of the invention and together with the description to explain the principles of the invention. In the drawings:

FIG. 1A is a cross-sectional view of a conventional SGT MOSFET of prior art.

FIG. 1B is the doping profile along A-B illustrated in FIG. 1A.

FIG. 1C is a cross-sectional view of another SGT MOSFET of prior art.

FIG. 2A is a cross-sectional view of a preferred embodiment according to the present invention.

FIG. 2B is the doping profile along A′-B′ illustrated in FIG. 2A.

FIG. 2C is a cross-sectional view of another preferred embodiment according to the present invention.

FIG. 3A is a cross-sectional view of another preferred embodiment according to the present invention.

FIG. 3B is a cross-sectional view of another preferred embodiment according to the present invention.

FIG. 3C is a cross-sectional view of another preferred embodiment according to the present invention.

FIG. 4A is a cross-sectional view of another preferred embodiment according to the present invention.

FIG. 4B is a cross-sectional view of another preferred embodiment according to the present invention.

FIG. 5 is a cross-sectional view of another preferred embodiment according to the present invention.

FIGS. 6A-6I are a serial of side cross-sectional views for showing the processing steps for fabricating the trench MOSFET of FIG. 3A.

### DETAILED DESCRIPTION OF THE EMBODIMENTS

In the following Detailed Description, reference is made to the accompanying drawings, which forms a part thereof, and in which is shown by way of illustration specific embodiments in which the invention may be practiced. In this regard, directional terminology, such as “top”, “bottom”, “front”, “back”, etc., is used with reference to the orientation of the Figure(s) being described. Because components of embodiments can be positioned in a number of different orientations, the directional terminology is used for purpose of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims. It is to be understood that the features of the various exemplary embodiments described herein may be combined with each other, unless specifically noted otherwise.

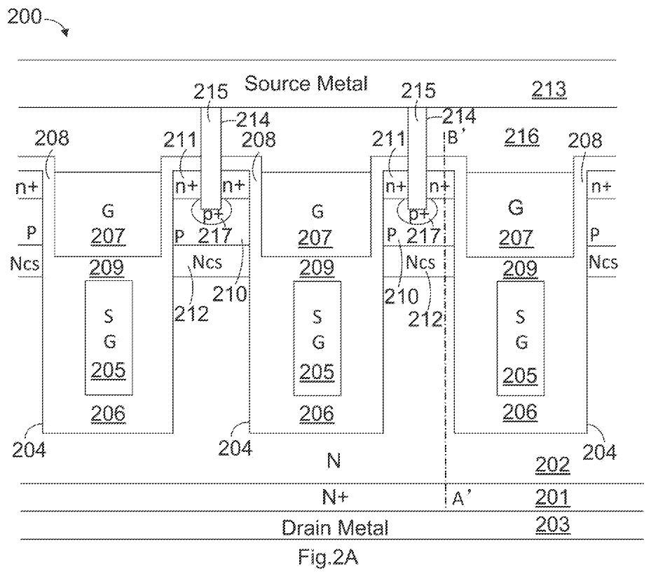

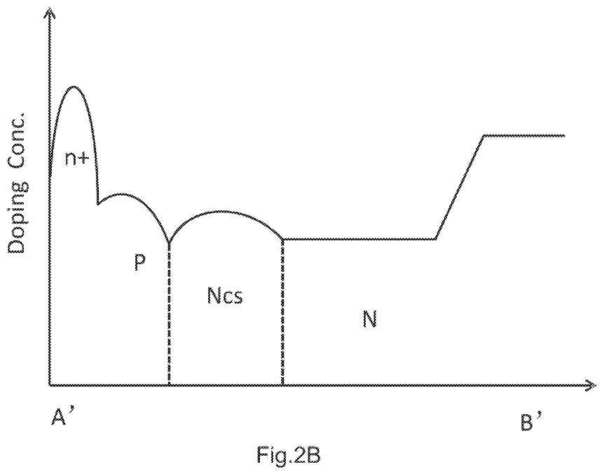

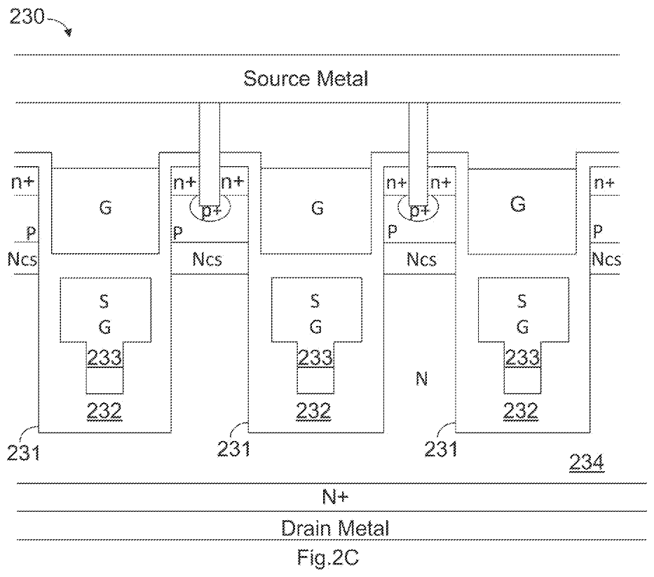

Please refer to FIG. 2A for a preferred embodiment of this invention, wherein an N-channel SGT MOSFET 200 is formed on an N+ substrate 201 with a less doped single N epitaxial layer 202 extending thereon, wherein the N+ substrate is coated with back metal on rear side as a drain metal 203. Inside the N epitaxial layer 202, a plurality of gate trenches 204 are formed vertically downward, with each filled with: a shielded gate electrode (SG, as illustrated) 205 disposed in lower portion and padded by a first insulating film 206, wherein the first insulating film 206 is a single oxide film has uniform thickness along bottom and lower sidewalls of the gate trenches 204 in this embodiment, a gate electrode (G, as illustrated) 207 disposed in upper portion and surrounded by a gate oxide 208 along sidewalls of the gate trench, wherein the gate oxide 208 has a thickness less than the first insulating film 206; the shielded gate electrode 205 and the gate electrode 207 are insulated from each other by an IPO film 209. Between every two adjacent gate trenches 204, P body regions 210 with n+ source regions 211 thereon are extending near top surface of the N epitaxial layer 202, and a current spreading region (Ncs, as illustrated) 212 is formed underneath each P body region 210 with higher doping concentration than the N epitaxial layer 202, please refer to the doping profile along A′-B′ as shown in FIG. 2B, to help to reduce the on-resistance without degrading breakdown voltage. The n+ source regions 211, the P body regions 210 and the shielded gate electrodes 205 are all shorted to a source metal 213 through a plurality of trench contacts 214, which are filled with metal plugs 215, penetrating through a thick insulating layer 216, the n+ source regions 211 and into the P body regions 210, wherein the trench contacts 214 are surrounded by p+ doped regions 217 to reduce the contact resistance between the P body regions 210 and the metal plugs 215.

Please refer to FIG. 2C for another preferred embodiment of the present invention, the N-channel SGT MOSFET 230 has a similar structure to FIG. 2A, except that, inside each of the gate trenches 231, the first insulating film 232 between the shielded gate electrode 233 and the N epitaxial layer 234 has two stepped oxide structure having greater thickness padding lower portion and bottom of the shielded gate electrode 233 than padding upper portion of the shielded gate electrode 233.

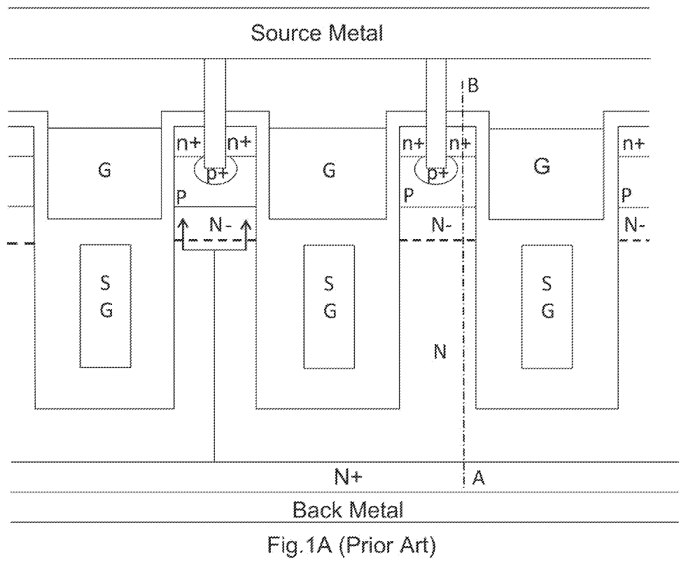

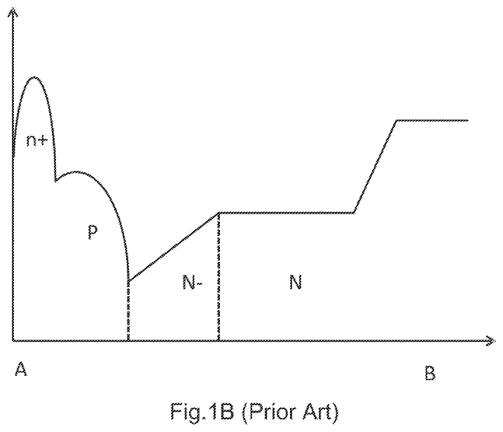

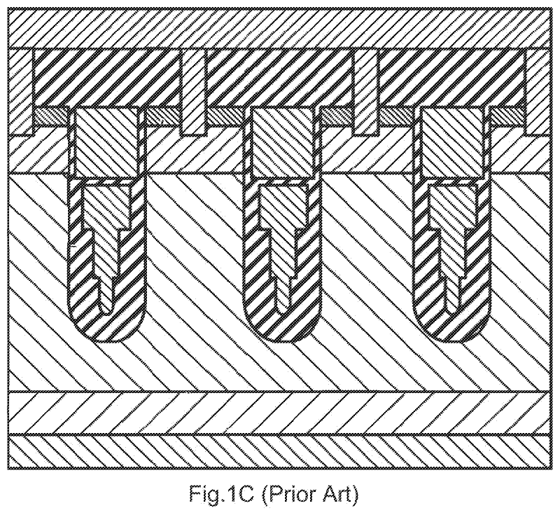

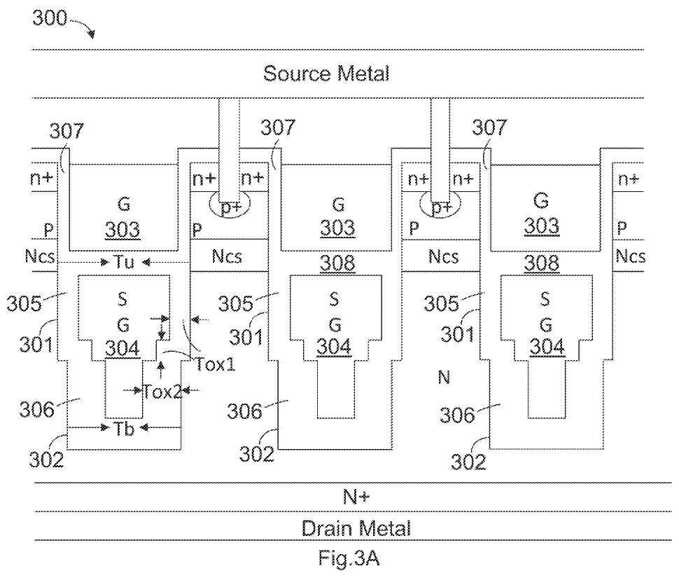

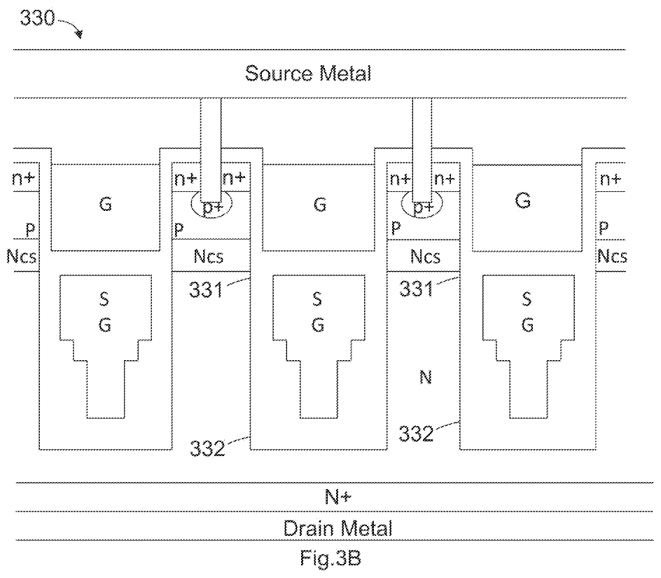

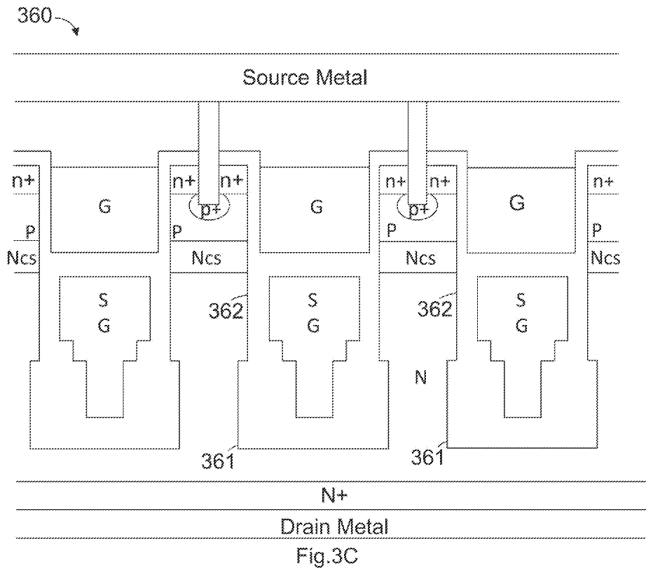

Please refer to FIG. 3A for another preferred embodiment of the present invention, the N-channel SGT MOSFET 300 has a similar structure to FIG. 2C, except that, each of the gate trenches further comprises dual gate trenches including a first type gate trench 301 and a second type gate trench 302 right below, wherein the first type gate trench 301 is filled with a gate electrode 303 and upper portion of a shielded gate electrode, the second type gate trench 302 is filled with lower portion of the shielded gate electrode 304. According to this embodiment, trench width (Tb) of the second type gate trench 302 is less than trench width (Tu) of the first type gate trench 301, accordingly, the insulating film padding the shielded gate electrode 304 has multiple stepped oxide structure comprising: a first insulating film 305 having thickness Tox1, padding upper portion sidewalls of the shielded gate electrode 304 along lower portion sidewalls and bottoms of the first type gate trench 301; and a second insulating film 306 having thickness Tox2, padding lower portion of the shielded gate electrode 304 along sidewalls and bottom of the second type gate trench 302, wherein Tox2>Tox1. Besides, the gate electrode 303 padded by a gate oxide 307 along upper portion sidewalls of the first type gate trench 301 is insulated from the shielded gate electrode 304 by an IPO film 308, wherein the gate oxide 307 has thickness less than the first insulating film 305, the second insulating film 306 and the IPO film 308. The FIG. 3A has three stepped oxide structure in the dual gate trenches formed by the LOCOS technique, which is different from the prior art as shown in FIG. 1C which has a two stepped oxide structure in a single gate trench formed by multiple polysilicon etching and multiple oxide etching. The three stepped oxide structure is closer to gradient oxide structure than the two stepped oxide structure for better breakdown voltage improvement.

Please refer to FIG. 3B for another preferred embodiment of the present invention, the N-channel SGT MOSFET 330 has a similar structure to FIG. 3A, except that, the first type gate trench 331 has same trench width as the second type gate trench 332, therefore the N-channel SGT MOSFET 330 also has a similar structure to FIG. 2C, except the number of oxide steps in FIG. 3B greater than in FIG. 2C.

Please refer to FIG. 3C for another preferred embodiment of the present invention, the N-channel SGT MOSFET 360 has a similar structure to FIG. 3A, except that, second type gate trench 361 has trench width greater than the first type gate trench 362.

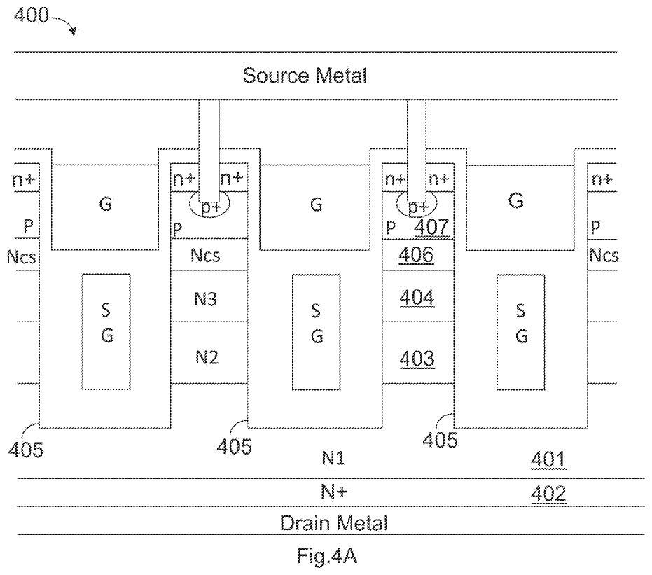

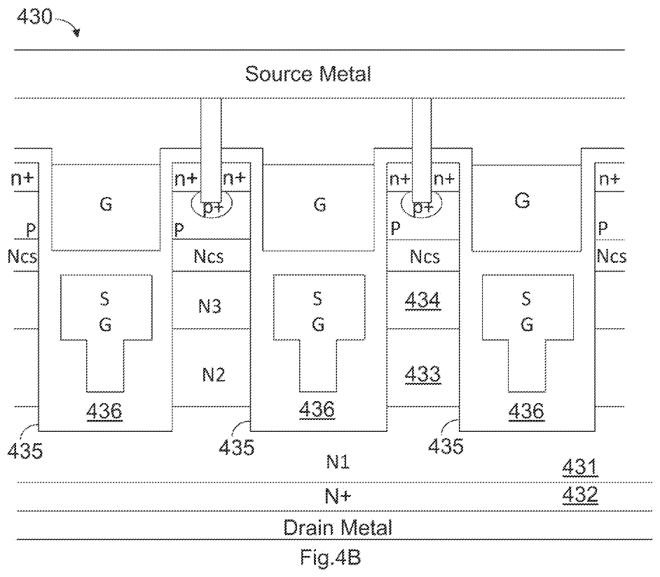

Please refer to FIG. 4A for another preferred embodiment of the present invention, the N-channel SGT MOSFET 400 has a similar structure to FIG. 2A, except that, the epitaxial layer in FIG. 4A has three sub-epitaxial layers, comprising: a bottom N1 epitaxial layer 401 extending onto the N+ substrate 402 and having resistivity R1; a middle N2 epitaxial layer 403 extending onto the bottom N1 epitaxial layer 401 and having resistivity R2; and a top N3 epitaxial layer 404 extending onto the middle N2 epitaxial layer 403 and having resistivity R3, wherein R2<R3<R1 or R2<R1<R3. The gate trenches 405 are penetrating through the top N3 epitaxial layer 404, the middle N2 epitaxial layer 403 and terminating in the bottom N1 epitaxial layer 401, to provide a higher resistivity epitaxial layer near trench bottom corners for preventing an early breakdown, while to provide a lower resistivity epitaxial layer above the trench bottom to achieve a reduced device resistance. The current spreading regions 406 are sandwiched between the P body regions 407 and the top N3 epitaxial layer 404, and have doping concentration higher than any of the three sub-epitaxial layers.

Please refer to FIG. 4B for another preferred embodiment of the present invention, the N-channel SGT MOSFET 430 has a similar structure to FIG. 2C, except that, the epitaxial layer in FIG. 4B has three sub-epitaxial layers, comprising: a bottom N1 epitaxial layer 431 extending onto the N+ substrate 432 and having resistivity R1; a middle N2 epitaxial layer 433 extending onto the bottom N1 epitaxial layer 431 and having resistivity R2; and a top N3 epitaxial layer 434 extending onto the middle N2 epitaxial layer 433 and having resistivity R3, wherein R3<R2<R1. The gate trenches 435 are penetrating through the top N3 epitaxial layer 434, the middle N2 epitaxial layer 433 and terminating in the bottom N1 epitaxial layer 431. The middle N2 epitaxial layer 433 is adjacent to lower portion of the first insulating film 436 while the top N3 epitaxial layer 434 is adjacent to upper portion of the first insulating film 436.

Please refer to FIG. 5 for another preferred embodiment of the present invention, the N-channel SGT MOSFET 500 has a similar structure to FIG. 3A, except that, the epitaxial layer in FIG. 5 has three sub-epitaxial layers, comprising, a bottom N1 epitaxial layer 501 extending onto the N+ substrate 502 and having resistivity R1; a middle N2 epitaxial layer 503 extending onto the bottom N1 epitaxial layer 501 and having resistivity R2; and a top N3 epitaxial layer 504 extending onto the middle N2 epitaxial layer 503 and having resistivity R3, wherein R3<R2<R1. The top N3 epitaxial layer 504 has a bottom surface located below the gate electrode 505 is adjacent to the first insulating film 506 padding upper portion of the shielded gate electrode 507 in the first type gate trench 508. The middle N2 epitaxial layer 503 is adjacent to the second insulating film 509 padding lower portion of the shielded gate electrode 507 in the second type gate trench 510 which has a bottom surface in the lower N1 epitaxial layer 501.

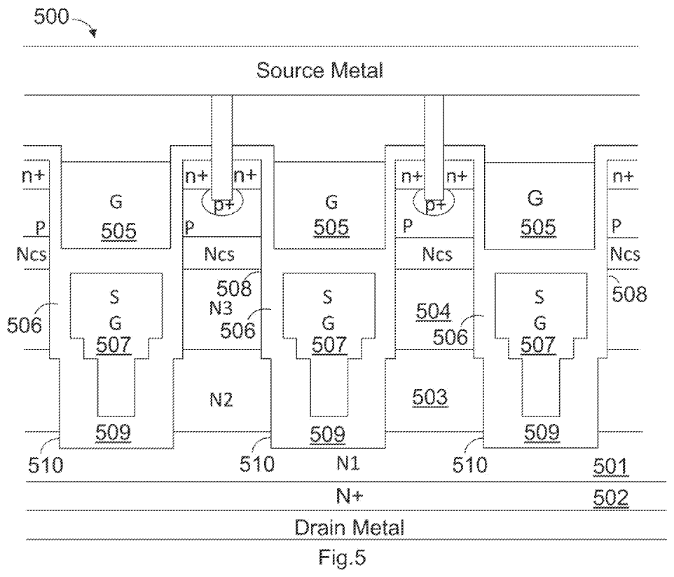

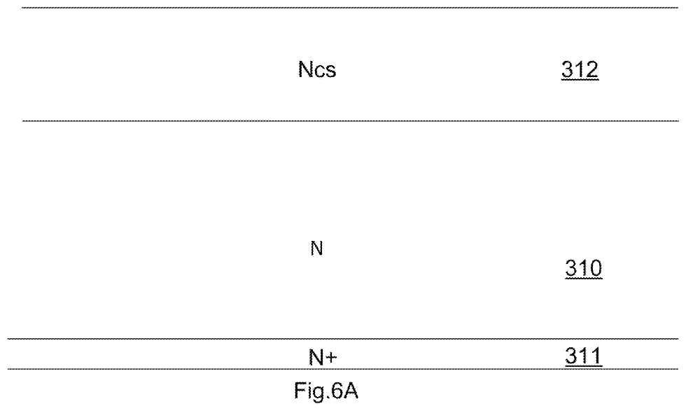

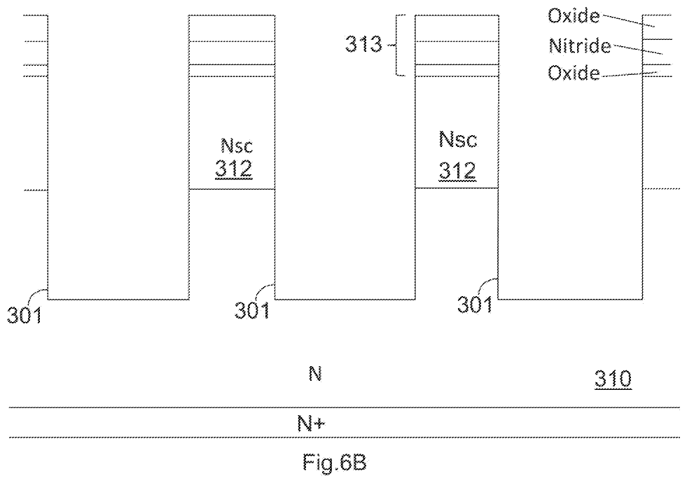

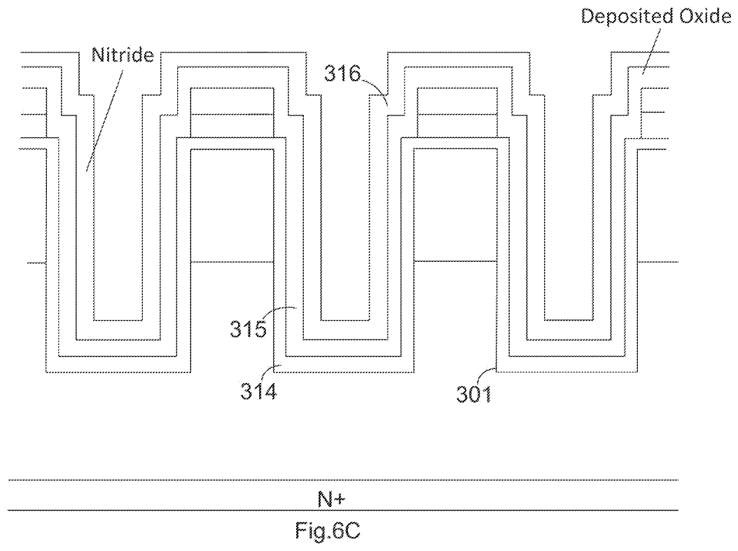

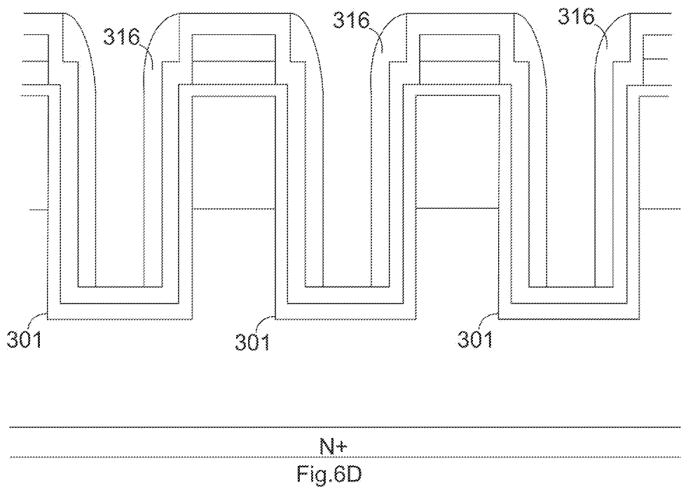

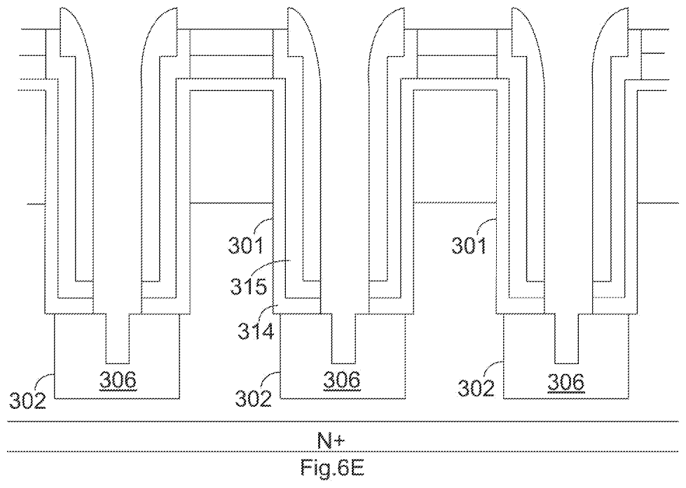

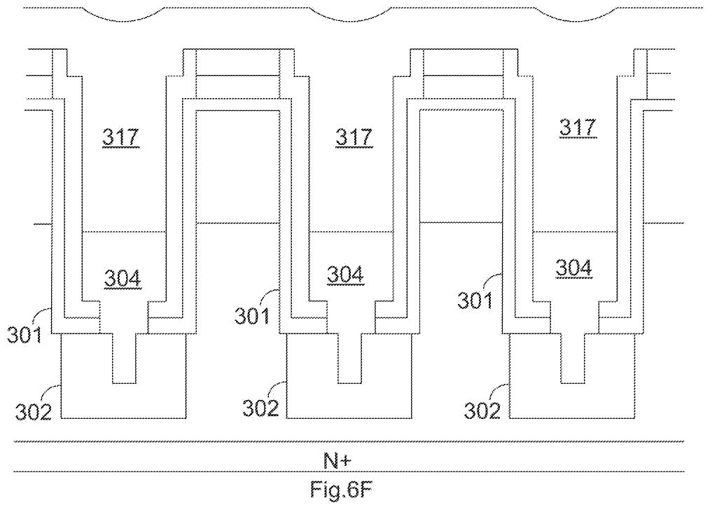

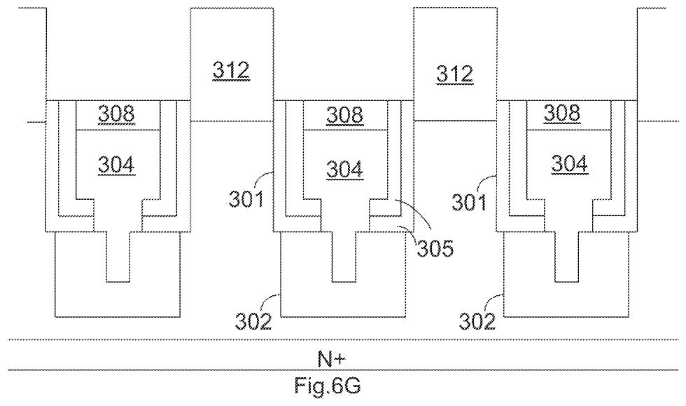

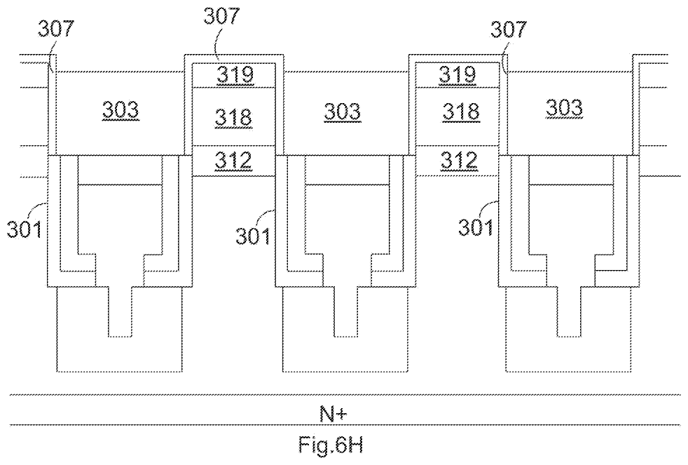

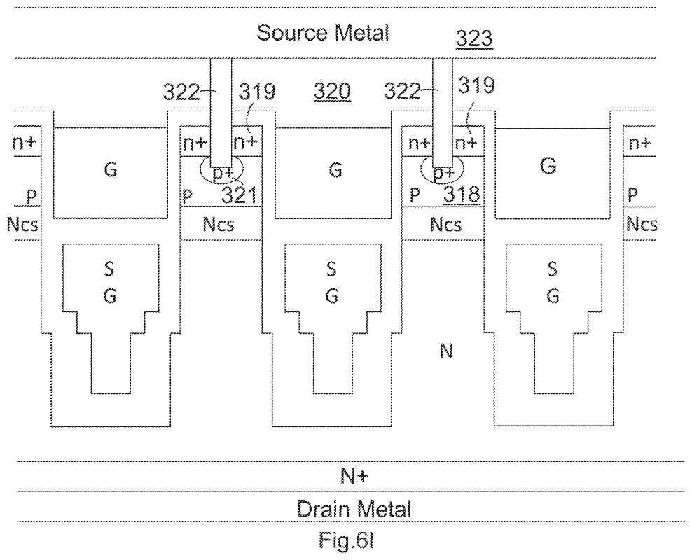

FIGS. 6A-6I are a serial of exemplary steps that are performed to form the invented embodiment of FIG. 3A. In FIG. 6A, an N epitaxial layer 310 is grown on an N+ substrate 311, then, a current spreading region 312 is formed on top of the N epitaxial layer 310 by either implantation of As or Phosphorus dopant into N epitaxial layer 310 or by growing an additional N type doped epitaxial layer.

In FIG. 6B, a hard mask 313 composed of oxide/first nitride/oxide is deposited on top of the current spreading region 312. After applying a trench mask (not shown), a plurality of first type gate trenches 301 are etched penetrating the hard mask 313, the current spreading region 312 and terminating in the N epitaxial layer 310.

In FIG. 6C, after removing the trench mask, growing a thermal oxide layer 314 lining inner surface of the first type gate trenches 301, then, a deposited oxide layer 315 is formed covering top the thermal oxide 314 and outer surface of the hard mask, wherein the deposited oxide layer 315 is composed of TEOS or SA CVD oxide. Next, onto the deposited oxide layer 315, a second nitride layer 316 is deposited, as illustrated.

In FIG. 6D, a step of anisotropic etching of nitride layer is performed to remove the second Nitride layer 316 from bottom of the first type gate trenches 301.

In FIG. 6E, a step of anisotropic etching of oxide layer is performed to remove the deposited oxide layer 315 and the thermal oxide layer 314 from bottom of the first type gate trenches 301. Then, a step of anisotropic trench etching is performed to form a plurality of second type gate trenches 302 right below the first type gate trenches 301. Next, growing another oxide layer lining sidewalls and bottoms of the second type gate trenches 302 to serve as the second insulating film 306.

In FIG. 6F, the second nitride layer 316 is first removed away and followed by a step of doped polysilicon deposition and etching back to fill the second type gate trenches 302 and lower portion of the first type gate trenches 301 to serve as the shielded gate electrodes 304. Then, a HDP (High Density Plasma) oxide 317 is deposited covering top of the shielded gate electrodes 304.

In FIG. 6G, a step of oxide CMP (Chemical Mechanical Polish) is carried out till touches the first nitride layer in the hard mask (not shown), then, after removing the first nitride layer, a step of wet oxide etching is performed to a target depth below top surface of the current spreading regions 312. Therefore, the two oxide layers (314 and 315 in FIG. 6E) remained in lower portion of the first type gate trenches 301 together form the first insulating film 305, and the HDP oxide layer remained on top of the shielded gate electrodes forms the IPO film 308.

In FIG. 6H, an oxide layer is grown lining upper sidewalls of the first type gate trenches 301 to serve as gate oxide layer 307. Another doped polysilicon is deposited and then etched back by CMP to fill upper portion of the first type gate trenches 301 to serve as gate electrodes 303. After that, a step of P type dopant ion implantation and diffusion are carried out to form P body regions 318 onto the current spreading regions 312, then a step of N type dopant ion implantation and diffusion are carried out to form n+ source regions 319 onto the P body regions 318.

In FIG. 6I, after depositing a thick insulating layer 320, a contact mask (not shown) is applied, followed by successive dry oxide etching and dry silicon etching, a plurality of contact holes are formed penetrating through the thick insulating layer 320, the n+ source regions 319 and into the P body regions 318. Next, a step of BF2 ion implantation is carried out through the contact holes to form p+ doped regions 321 wrapping bottoms of the contact holes underneath the n+ source regions 319. To fill the contact holes, a layer of Ti/TiN and tungsten are deposited successively, and then etch back to form a plurality of metal plugs 322 in the contact holes. Then, a front metal is deposited covering top of the thick insulating layer 320 and patterned by applying a metal mask and a step of etching back to serve as source metal 323.

For all the described preferred embodiment, the first type conductivity type is N type and the second conductivity type is P type, the opposite is also applicable to the present invention when the first type is P type and the first type is N type.

Although the present invention has been described in terms of the presently preferred embodiments, it is to be understood that such disclosure is not to be interpreted as limiting. Various alternations and modifications will no doubt become apparent to those skilled in the art after reading the above disclosure. Accordingly, it is intended that the appended claims be interpreted as covering all alternations and modifications as fall within the true spirit and scope of the invention.

What is claimed is:

1. A SGT MOFET formed in an epitaxial layer of a first conductivity type onto a substrate of said first conductivity type, further comprising:
a plurality of gate trenches surrounded by source regions of said first conductivity type are encompassed in body regions of a second conductivity type near a top surface of said epitaxial layer, each of said gate trenches is filled with a gate electrode and a shielded gate electrode, wherein said shielded gate electrode is insulated from said epitaxial layer by a first insulating film, said gate electrode is disposed above said shielded gate electrode and insulated from said epitaxial layer by a gate oxide, said shielded gate electrode and said gate electrode is insulated from each other by an IPO film, said gate oxide surrounds said gate electrode and has less thickness than said first insulating film;
an oxide charge balance region is formed between adjacent of said gate trenches;
a current spreading region of said first conductivity type is formed below each of said body regions between adjacent of said gate trenches, and has higher doping concentration than said epitaxial layer; and
said body regions, said shielded gate electrode and said source regions are shorted to a source metal through a plurality of trench contacts.

2. The SGT MOSFET of claim 1, wherein said first insulating film is a single oxide film having uniform thickness and said epitaxial layer is a single epitaxial layer having uniform doping concentration.

3. The SGT MOSFET of claim 1, wherein said first insulating film is a single oxide film having uniform thickness and said epitaxial layer comprises at least three sub-epitaxial layers of different doping concentration including a bottom epitaxial layer with resistivity R1, a middle epitaxial layer with resistivity R2 and a top epitaxial layer with resistivity R3, wherein R2<R3<R1 or R2<R1<R3.

4. The SGT MOSFET of claim 1, wherein said first insulating film has multiple stepped oxide structure having greatest thickness padding lower portion and bottoms of said shielded gate electrode, and said epitaxial layer is a single epitaxial layer having uniform doping concentration.

5. The SGT MOSFET of claim 1, wherein said first insulating film has multiple stepped oxide structure having greatest thickness along lower portion sidewalls and bottoms of said gate trenches, and said epitaxial layer comprises at least three sub-epitaxial layers of different doping concentration including a bottom epitaxial layer with resistivity R1, a middle epitaxial layer with resistivity R2 and a top epitaxial layer with resistivity R3, wherein R3<R2<R1.

6. The SGT MOSFET of claim 1, wherein said first insulating film has two stepped oxide structure having a lower portion oxide along lower portion sidewalls and bottom of said gate trenches with greater thickness than an upper portion oxide, and said epitaxial layer comprises at least three sub-epitaxial layers of different doping concentration including a bottom epitaxial layer with resistivity R1, a middle epitaxial layer with resistivity R2 and a top epitaxial layer with resistivity R3, wherein bottom surface of said gate trenches is disposed in said bottom epitaxial layer, said middle epitaxial layer is adjacent to said lower portion oxide, and said top epitaxial layer is adjacent to said upper portion oxide.

7. A SGT MOSFET formed in an epitaxial layer of a first conductivity type onto a substrate of said first conductivity type, further comprising:
a plurality of gate trenches surrounded by source regions of said first conductivity type are encompassed in body regions of a second conductivity type near a top surface of said epitaxial layer, each of said gate trenches is filled with a gate electrode and a shielded gate electrode, wherein said gate electrode is disposed above said shielded gate electrode and insulated from said epitaxial layer by a gate oxide;
an oxide charge balance region is formed between adjacent of said gate trenches;
a current spreading region formed below each of said body regions between adjacent of said gate trenches;
said body regions, said shielded gate electrode and said source regions are shorted to a source metal through a plurality of trench contacts;
each of said gate trenches further comprises dual gate trenches including a first type gate trench and a second type gate trench in said epitaxial layer, wherein:
said first type gate trench is filled with said gate electrode, and upper portion of said shielded gate electrode padded by a first insulating film along lower portion sidewalls and bottoms of said first type gate trench;
said second type gate trench disposed below said first type gate trench is filled with lower portion of said shielded gate electrode padded by a second insulating film along sidewalls and bottom of said second type gate trench;
said second insulating film has thickness greater than said first insulating film;
said shielded gate electrode and said gate electrode are insulated from each other by an IPO film; and
said gate oxide surrounding said gate electrode has less thickness than said first insulating film, said second insulating film and said IPO film, respectively.

8. The SGT MOSFET of claim 7, wherein said second type gate trench has trench width less than said first type gate trench.

9. The SGT MOSFET of claim 7, wherein said second type gate trench has trench width same as said first type gate trench.

10. The SGT MOSFET of claim 7, wherein said second type gate trench has trench width greater than said first type gate trench.

11. The SGT MOSFET of claim 7, wherein said first insulating film is combination of a thermal oxide and a deposited oxide.

12. The SGT MOSFET of claim 7, wherein said first insulating film is a thermal oxide.

13. The SGT MOSFET of claim 7, wherein said epitaxial layer is a single epitaxial layer with uniform doping concentration.

14. The SGT MOSFET of claim 7, wherein said epitaxial layer comprises at least three sub-epitaxial layers of different doping concentration including a bottom epitaxial layer with resistivity R1, a middle epitaxial layer with resistivity R2 and a top epitaxial layer with resistivity R3, wherein R3<R2<R1.

15. The SGT MOSFET of claim 14, wherein said each of gate trenches has a bottom surface disposed in said bottom epitaxial layer, said top epitaxial layer is adjacent to said first insulating film and said middle epitaxial layer is adjacent to said second insulating film.

16. A method for manufacturing a SGT MOSFET, comprising:
growing an epitaxial layer of a first conductivity type onto a substrate heavily doped with said first conductivity type;
forming a current spreading region on top of said epitaxial layer;
applying a hard mask composed of oxide/first nitride/oxide layers onto top surface of said epitaxial layer and forming a plurality of first type gate trenches by definition of said hard mask;
growing a thermal oxide layer lining inner surface of said first type gate trenches;
forming deposited oxide layer covering said thermal oxide layer and outer surface of said hard mask;
depositing a second nitride layer covering said deposited oxide layer,
performing anisotropic etch of nitride layer to remove said second nitride layer from bottom of the first type gate trenches;
performing anisotropic etch of oxide layer to remove said thermal oxide layer and said deposited oxide layer from bottom of the first type gate trenches;
performing anisotropic trench etch to form a plurality of second type gate trenches below said first type gate trenches;
growing another oxide layer lining inner surface of said second type gate trenches to serve as a second insulating film;
removing said second nitride layer; and
depositing a first doped polysilicon layer and etching back to form shielded gate electrodes.

17. The SGT MOSFET of claim 16, further comprising:
depositing a layer of HDP oxide;
performing oxide CMP till touching the first nitride layer in said hard mask and removing said first nitride layer; and
performing wet oxide etch to a target depth below top surface of said current spreading regions.

18. The SGT MOSFET of claim 16, wherein said current spreading region is formed by implanting dopant of said first conductivity type into said epitaxial layer.

19. The SGT MOSFET of claim 16, wherein said current spreading region is formed by growing an additional epitaxial layer of said first conductivity type.
